(19) United States
(12) Patent Application Publication
(10) Pub. No.: US 2008/0025023 A1
(43) Pub. Date: Jan. 31, 2008

(54) Light-emitting heat-dissipating device and manufacturing method thereof

(75) Inventors: Yu-Ping Hsieh, Taoyuan Hsien (TW); Yi-Sheng Lee, Taoyuan Hsien (TW); Chin-Ming Cheng, Taoyuan Hsien (TW); Chih-Hao Yu, Taoyuan Hsien (TW); Yu-Ching Chang, Taoyuan Hsien (TW); Yi-Hong Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/878,253

(22) Filed: Jul. 23, 2007

(30) Foreign Application Priority Data
Jul. 28, 2006 (TW) 095127658

(51) Int. Cl. F21V 29/00; H05K 3/34

(52) U.S. Cl. 362/249; 29/840; 362/294

(57) ABSTRACT

A light-emitting heat-dissipating device includes a substrate and at least a light-emitting package module capable of generating heat. The substrate includes at least a recess and at least one thermally conducting element disposed in the recess. The light-emitting package module is disposed on the thermally conducting element and electrically connected to the substrate of the substrate via solder joints. A manufacturing method of the light-emitting heat-dissipating device is also disclosed.

### CROSS REFERENCE TO RELATED APPLICATIONS

This Non-provisional application claims priority under 35 U.S.C. §119(a) on Patent Application No(s). 095127658 filed in Taiwan, Republic of China on Jul. 28, 2006, the entire contents of which are hereby incorporated by reference.

### BACKGROUND OF THE INVENTION

1. Field of Invention

The invention relates to a light-emitting heat-dissipating device and a manufacturing method thereof, and, in particular, to a light-emitting heat-dissipating device for dissipating heat using a heat pipe and a manufacturing method thereof.

2. Related Art

Due to the progress of the technology, various electronic products need to have more and more functions. In addition to the continuous upgrade of the speed of the desktop computer, portable mobile electronic devices, such as personalized products including a notebook computer, a mobile phone, a mini CD and a hand-held computer, have become the important trend of the development. However, as the product performance is getting stronger and stronger, the integration of the used electronic element is getting higher and higher, and the generated heat is thus increased. Therefore, the heat dissipating efficiency directly influences the reliability and the lifetime of the electronic element.

Illustrations will be made by taking a light emitting diode (LED) package module as an example. Referring to FIG. 1, the conventional LED package module 1 includes a package 11, a LED chip 12 and a lead frame 13. The LED chip 12 is electrically connected to the lead frame 13 by wire bonding method and packaged in the package 11 with an end portion of the lead frame 13 exposed to the package 11. When the LED package module 1 is being used, the heat generated by the LED chip 12 is dissipated through the lead frame 13. Thus, the power of the LED package module is limited to about 0.1 watt. However, when the LED package module 1 is used for a long time, the lead frame 13 cannot effectively dissipate the heat, and the accumulated heat influences the efficiency of the LED chip 12.

As shown in FIG. 2, another conventional LED package module 2 is similar to a combination of the structure of the LED package module 1 of FIG. 1 and a heat slug 21 disposed on a bottom surface of the LED chip 12. One surface of the heat slug 21 is exposed to the bottom surface of the package 11 so that the heat of the LED chip 12 is dissipated through the heat slug 21 and the lead frame 13 simultaneously. The heat slug 21 is made of a heat-conducting metal, such as copper or aluminum. This LED package module 2 is frequently used in the occasion in which the power is about more than 1 watt.

The heat slug 21 only dissipates the heat downwards. So, when the LED package module 2 is disposed on a circuit board (not shown), the heat of the LED package module 2 cannot be effectively dissipated but is transferred to the circuit board because the heat slug 21 contacts the circuit board. If the module is used for a long time, the heat dissipated from the LED chip 12 not only deteriorates the heat dissipation efficiency of the LED package module 2 but also makes the LED package module 2 and the circuit board be simultaneously damaged because the heat cannot be transferred to the environment.

Consequently, it is an important subject to provide a light-emitting heat-dissipating device capable of quickly conducting heat and effectively dissipating the heat, and a manufacturing method thereof.

### SUMMARY OF THE INVENTION

In view of the foregoing, the invention is to provide a light-emitting heat-dissipating device capable of dissipating heat rapidly and having the uniform temperature distribution, and a manufacturing method thereof.

According to the foregoing objects and others, the invention discloses a light-emitting heat-dissipating device including at least a light-emitting package module a substrate and at least a thermally conducting element. The substrate has at least a first recess on a surface. The thermally conducting element disposed in the first recess, and the light-emitting package module is disposed on the thermally conducting element. The thermally conducting element is preferably a heat pipe, and the light-emitting package module is preferably a light emitting diode (LED) package module.

According to the foregoing embodiment, the invention further comprises a supporter disposed below the substrate, the supporter having a second recess formed on a surface of the supporter. The second recess is correspondingly to the first recess, and the thermally conducting element is disposed in the first recess and the second recess. The supporter is made of metal, a thermal-conducting material or a polymer.

According to the foregoing objects and others, the invention also discloses a method of manufacturing a light-emitting heat-dissipating device including the steps of providing a substrate having at least a first recess formed on a surface of the substrate; disposing at least one thermally conducting element in the first recess; and disposing at least one light-emitting package module, which is capable of generating heat, on the thermally conducting element. The thermally conducting element is preferably a heat pipe, and the light-emitting package module is preferably a light emitting diode (LED) package module.

According to the foregoing embodiment, the invention further comprises to provide a supporter disposed below the substrate, the supporter having a second recess formed on a surface of the supporter. The second recess is correspondingly to the first recess, and the thermally conducting element is disposed in the first recess and the second recess. The supporter is made of metal, a thermal-conducting material or a polymer.

As mentioned above, compared with the prior art, the invention can transfer the heat from the heat end of the thermally conducting element to the cold end of the thermally conducting element to dissipate the heat. This method can dissipate the heat of the light-emitting package module more effectively and make the light-emitting heat-dissipating device have uniform temperature distribution so that the luminance and the color of the light-emitting package module achieve the uniform states and the reliability and the heat dissipating efficiency of the light-emitting heat-dissipating device can be enhanced.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED package module;

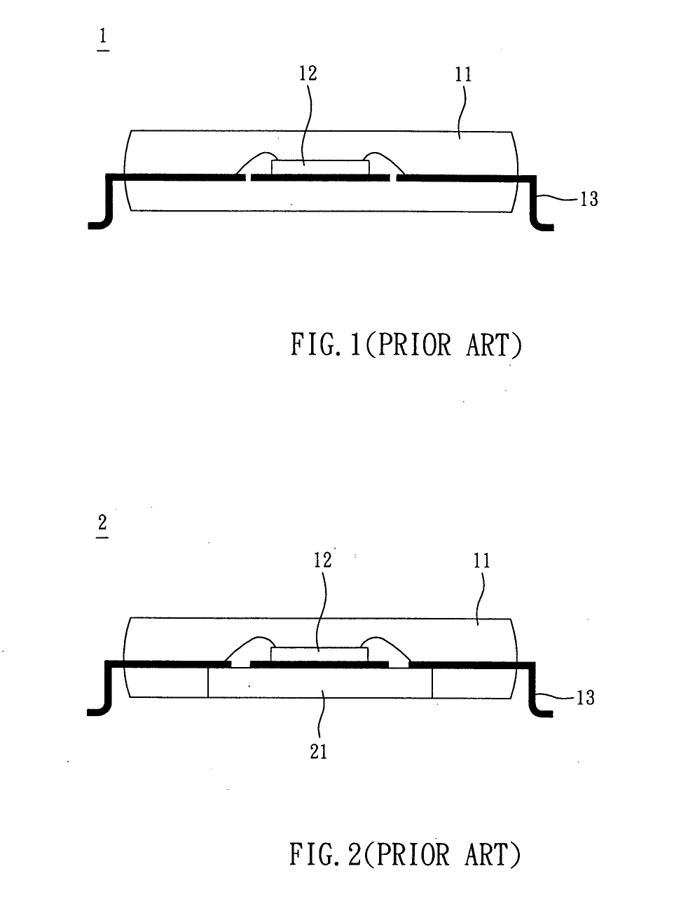

FIG. 2 is a schematic illustration showing another conventional LED package module;

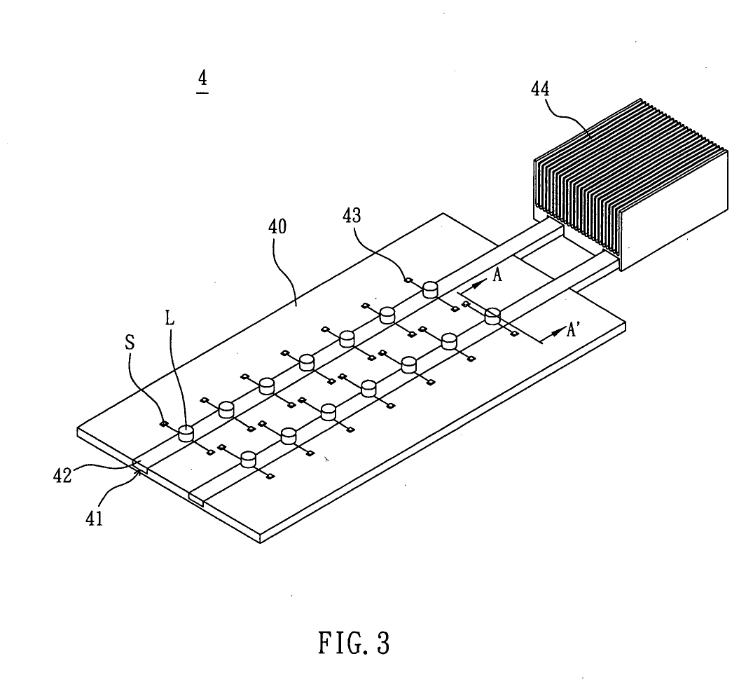

FIG. 3 is a schematic illustration showing a light-emitting heat-dissipating device according to an embodiment of the invention;

FIG. 4 is a cross-sectional view taken along the A-A′ line segment of FIG. 3;

FIG. 5 is a cross-sectional view showing another light-emitting heat-dissipating device according to the embodiment of the invention, wherein a heat dissipation element is disposed below a circuit board;

FIG. 6 is a flow chart showing a manufacturing method of the circuit board according to the embodiment of the invention;

FIG. 7 is a schematic illustration showing steps of the manufacturing method of the circuit board according to the embodiment of the invention;

FIG. 8 is a schematic illustration showing another light-emitting heat-dissipating device according to the embodiment of the invention;

FIG. 9 is a cross-sectional view taken along the B-B′ line segment of FIG. 8;

FIG. 10 is a flow chart showing the manufacturing method of the light-emitting heat-dissipating device of FIG. 8; and

FIGS. 11 to 13 are schematic illustrations showing steps of the manufacturing method of the light-emitting heat-dissipating device according to the embodiment of the invention.

### DETAILED DESCRIPTION OF THE INVENTION

The present invention will be apparent from the following detailed description, which proceeds with reference to the accompanying drawings, wherein the same references relate to the same elements.

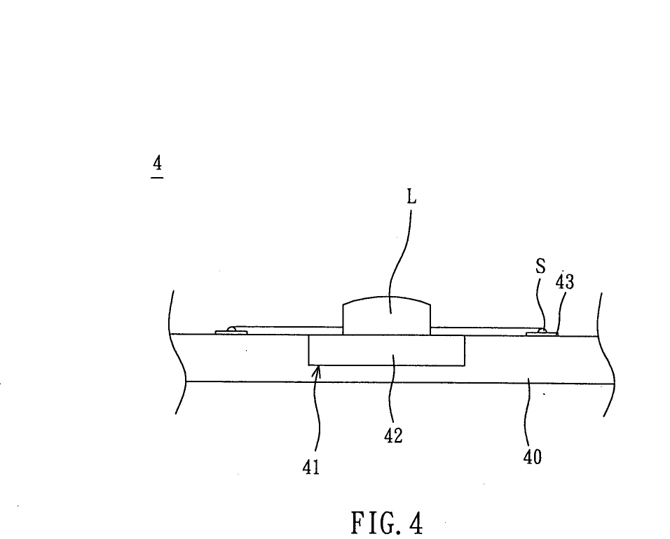

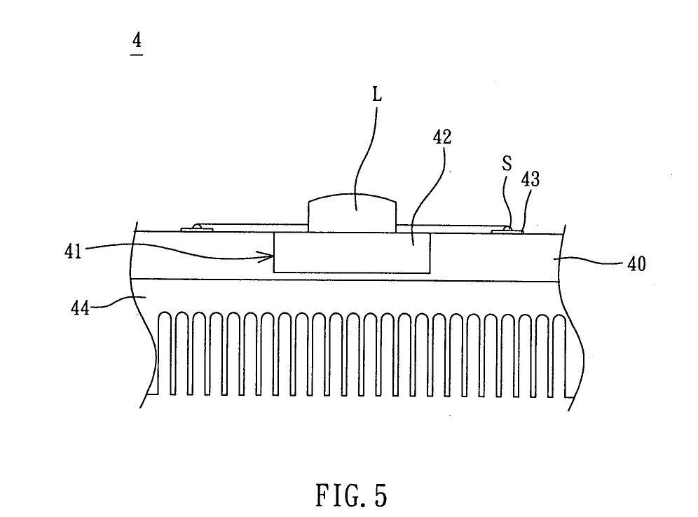

Referring to FIGS. 3 and 4, a light-emitting heat-dissipating device 4 according to an embodiment of the invention includes at least one light-emitting package module L and a substrate 40. The substrate 40 has at least one recess 41 and at least one thermally conducting element 42 disposed in the recess 41. The light-emitting package module L is disposed on the thermally conducting element 42. In this embodiment, the substrate 40 has a plurality of thermally conducting elements 42, and a plurality of light-emitting package modules L is disposed on each thermally conducting element 42.

The substrate 40 is not particularly restricted and may be a typical printed circuit board (PCB) or a low-temperature co-fired ceramic (LTCC) circuit board. The substrate 40 has a circuit layout on the surface, wherein a plurality of solder joints 43 is exposed from the surface of the substrate 40 and serves as connections between the light-emitting package modules L and the circuit layout of the substrate 40. The light-emitting package module L is a LED package module, such as a high power LED (HP LED) package module, a light emitting diode array (LED Array) package module, an organic light emitting diode (OLED) module or an organic light emitting diode array (OLED Array) package module. The thermally conducting element 42 is not particularly restricted and is preferably a heat pipe, such as a pulsating heat pipe or a loop heat pipe with the thermal coefficient substantially higher than 6000 W/m·K.

The heat pipe utilizes the cooling technology according to the property of absorbing or dissipating heat during the phase changing procedure. More particularly, the heat pipe is a vacuum body filled with a liquid that may easily evaporate (the evaporating temperature approaches the environment temperature), and is then encapsulated. One end of the heat pipe is an evaporating section, and the other end of the heat pipe is a condensing section. When one end of the heat pipe is heated, the liquid evaporates and vaporizes, and the vapor flows to the other end under the minor pressure difference and releases the heat to condense into the liquid. The liquid flows back to the evaporating section according to the capillary action. Thus, a circulating loop is formed so that the heat may be continuously dissipated. So, the heat pipe is suitable for the heat dissipation of the light-emitting package module L with any power, and is particularly suitable for the heat dissipation of the light-emitting package module with the high power.

More specifically, the light-emitting package module L disposed on the thermally conducting element 42 is connected to the solder joints 43 by surface mount technology (SMT) or object inserting method. The solder joints 43 are electrically connected to the circuit layout of the substrate 40. In this embodiment, the light-emitting package module L is electrically connected to the solder joints 43 via a conductive object S, such as a solder ball or a soldering paste, by surface mount technology method. According to the circuit layout of the substrate 40, the light-emitting package modules L may be connected together in series, in parallel, or in series and in parallel. Because the circuit layout pertains to the prior art and is not the important feature of the invention, detailed descriptions thereof will be omitted.

In this embodiment, the thermally conducting element 42 has a longitudinal shape, and may be disposed in the recess 41 of the substrate 40 by embedding, adhering or soldering method. The top surface of the thermally conducting element 42 may be higher than, lower than or equal to the top surface of the substrate 40. In this embodiment, the top surface of the thermally conducting element 42 is equal to the top surface of the substrate 40.

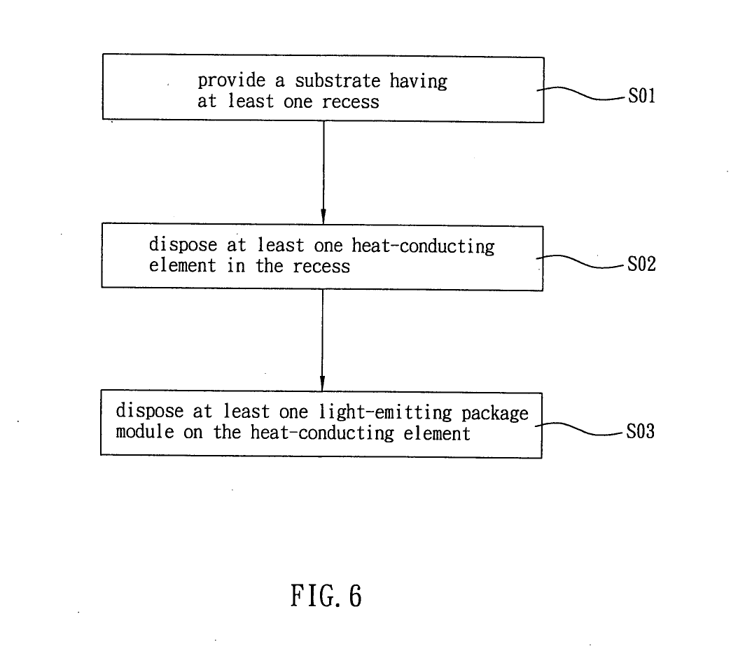

In addition, one end of the thermally conducting element 42 further extends out of the substrate 40 and is connected to a heat dissipation element 44. Of course, the position of the heat dissipation element 44 is not particularly restricted. In practice, the heat dissipation element 44 may be connected to the end portion of the thermally conducting element 42 (see FIG. 3), or with the bottom surfaces of the thermally conducting element 42 and the substrate 40 (see FIG. 5). The heat dissipation element 44 is not particularly restricted. In this embodiment, the heat dissipation element 44 includes a heat sink having a plurality of heat dissipation fins. The heat dissipation element 44 dissipates the heat introduced from the thermally conducting element 42. The heat dissipation element 44 may further include a fan (not shown) for producing an air stream to blow the heat sink and thus enhance the heat dissipating effect.

When the light-emitting heat-dissipating device 4 is operating, the heat produced by the light-emitting package module L is guided out from the package module L through the thermally conducting element 42 and transferred to the heat dissipation element 44 so that the heat is dissipated. The light-emitting heat-dissipating device 4 guides the heat generated by the light-emitting package module L through the thermally conducting element 42 in a single direction. That is, the heat is transferred from one end (heat end) between the thermally conducting element 42 and the light-emitting package module L to the other end (cold end) of the thermally conducting element 42, and then to the heat dissipation element 44 so that the heat may be dissipated. When the heat is dissipated using this method, the heat of the light-emitting package module(s) L may be simultaneously, evenly and rapidly dissipated no matter one or plural light-emitting package modules L are utilized so that the overall substrate 40 has the uniform temperature distribution. Thus, the luminance and colors of all light-emitting package modules L can achieve the uniform states, and the reliability and the heat dissipating efficiency of the light-emitting heat-dissipating device 4 may be enhanced.

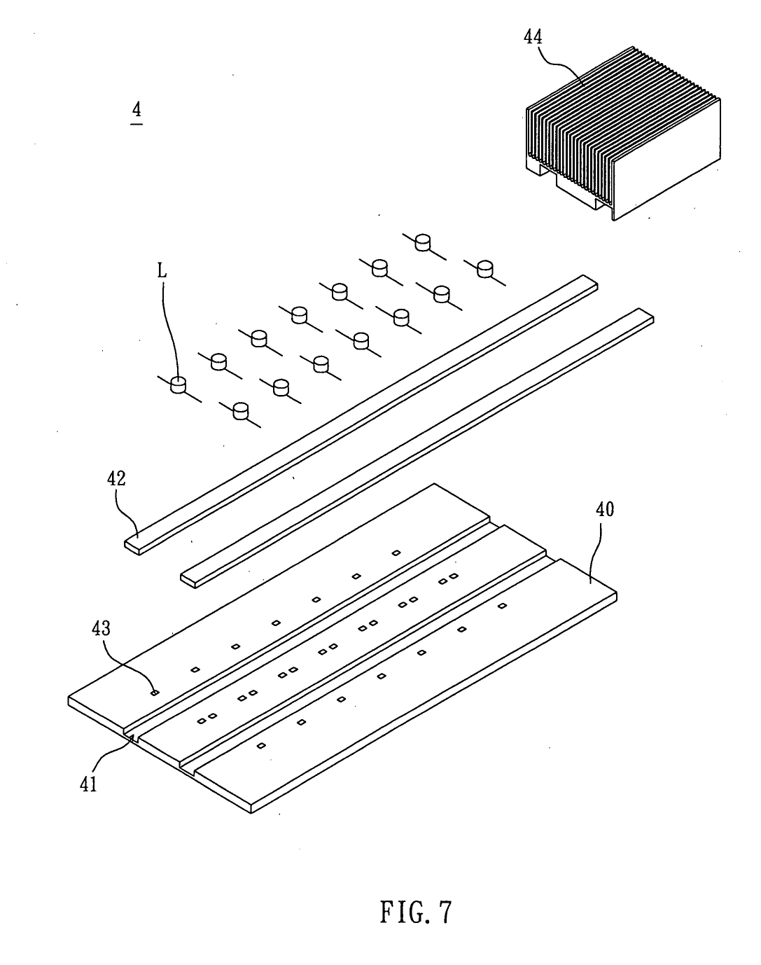

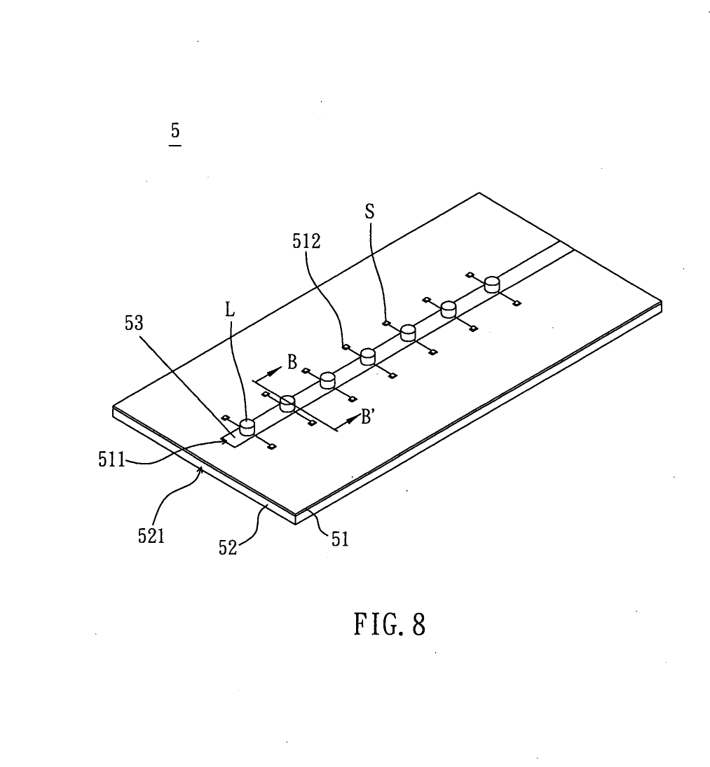

Referring to FIG. 6, the manufacturing method of the light-emitting heat-dissipating device 4 according to the embodiment includes steps S01 to S03. Referring to FIGS. 6 and 7, step S01 is performed to provide a substrate 40 having at least one recess 41. The surface of the substrate 40 has a plurality of solder joints 43, and the surface or the inner portion of the substrate 40 has a circuit layout. Step S02 is performed to dispose at least one thermally conducting element 42 in the recess 41. Step S03 is performed to dispose at least one light-emitting package module L on the thermally conducting element 42, wherein the light-emitting package module L is electrically connected to the solder joints 43 of the substrate 40. The light-emitting package module L on the thermally conducting element 42 is connected to the solder joints 43 of the substrate 40 by way of surface mount technology (SMT) or object inserting. Of course, it is also possible to connect a heat sink 44 with one end of the thermally conducting element 42.

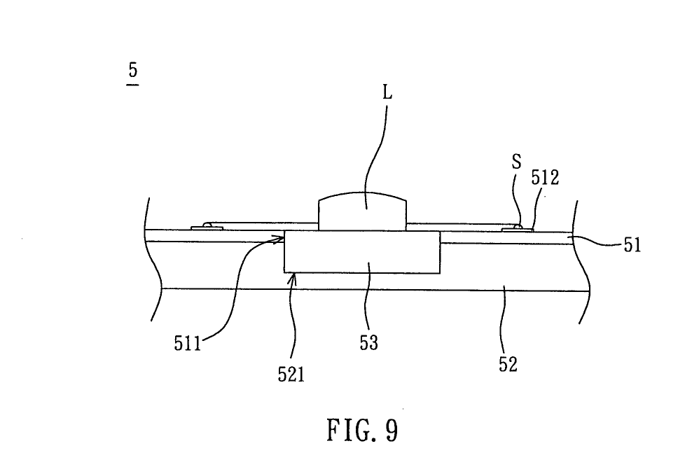

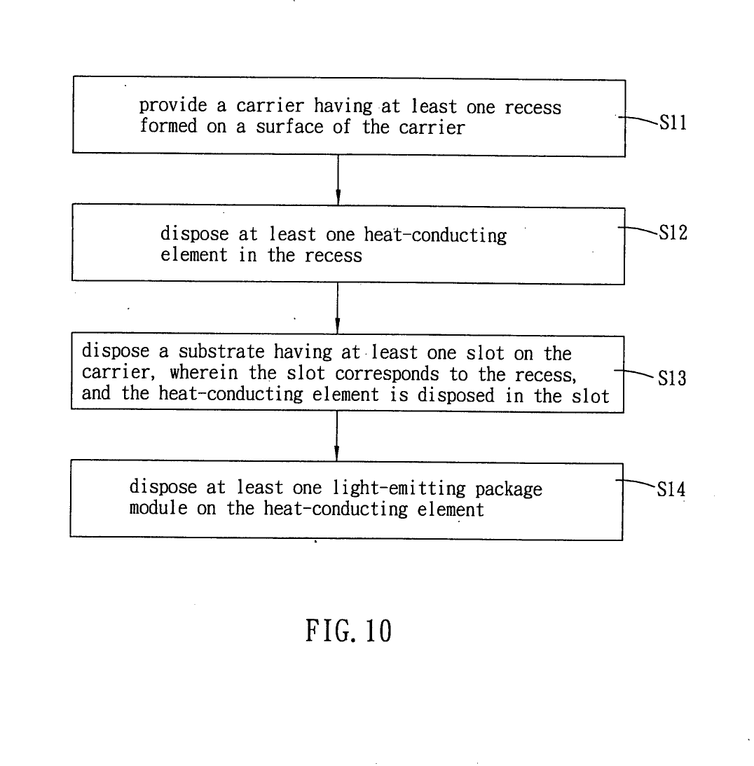

Referring to FIGS. 8 and 9, a light-emitting heat-dissipating device 5 according to the embodiment of the invention includes at least one light-emitting package module L, a substrate 51, a supporter 52 and at least one thermally conducting element 53.

In this embodiment, the substrate 51 has a slot 511 and may be a typical printed circuit board or a typical low-temperature co-fired ceramic circuit board in practice. So, the substrate 51 has a circuit layout (not shown), and one surface formed with solder joints 512 to be electrically connected to the circuit layout on the surface of the substrate 51 or inside the substrate 51.

In this embodiment, the supporter 52 has one surface formed with at least one recess 521 in which the thermally conducting element 53 is disposed. The material of the supporter 52 is not particularly restricted and may be a metal material or a polymer, but is preferably the material having the good heat conducting or heat dissipating property.

The substrate 51 is disposed on the supporter 52, and the slot 511 is correspondingly disposed on the recess 521 so that the thermally conducting element 53 is correspondingly disposed in the slot 511. The top surface of the thermally conducting element 53 may be higher than, lower than or level with the top surface of the substrate 51. In this embodiment, the top surface of the thermally conducting element 53 is level with the top surface of the substrate 51.

The light-emitting package module L is disposed on the thermally conducting element 53 and is electrically connected to the substrate 51 via the solder joints 512 simultaneously. In addition, the light-emitting package module L may further be connected to the solder joints 512 through a conductive object S. The connection between the light-emitting package module L and the substrate 51 of this embodiment is not particularly restricted, and may be implemented by way of surface mount technology or object inserting. Herein, the connection is implemented by way of surface mount technology.

In addition, the light-emitting package module L and the thermally conducting element 53 of this embodiment and the light-emitting package module L and the thermally conducting element 42 (see FIGS. 3 and 4) have the same structure, feature and effect, so detailed descriptions thereof will be omitted.

The light-emitting heat-dissipating device 5 is disposed in the recess 521 of the supporter 52 through the thermally conducting element 53. So, when the light-emitting package module L is used for a period of time and the heat is thus produced, the heat may be guided to the supporter 52 via the thermally conducting element 53. Since the supporter 52 is disposed below the substrate 51, the heat may be rapidly dissipated in a short time, and the temperatures of the light-emitting package module L and the substrate 51 may be decreased simultaneously so that the heat dissipating effect may be enhanced.

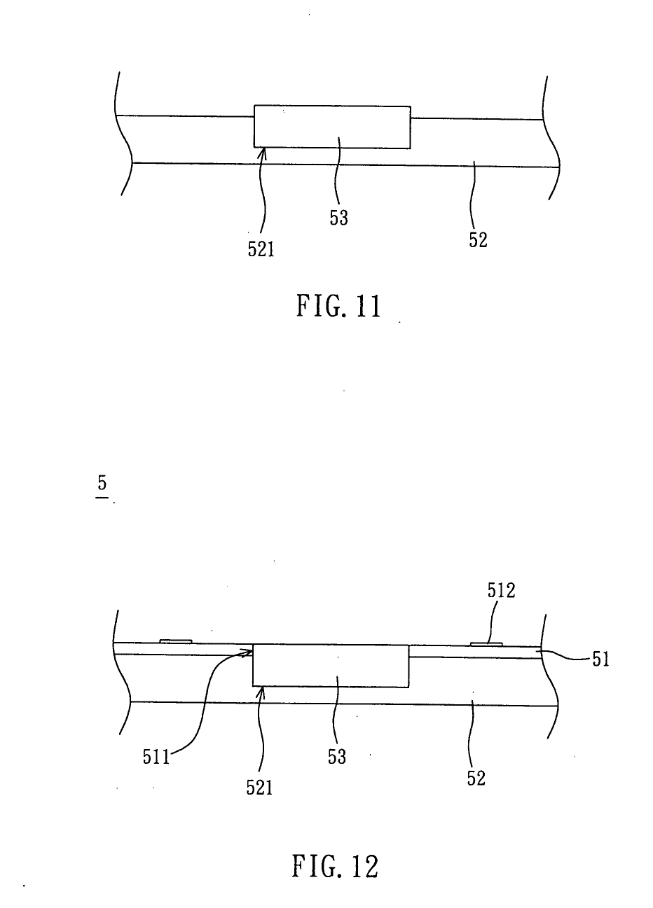

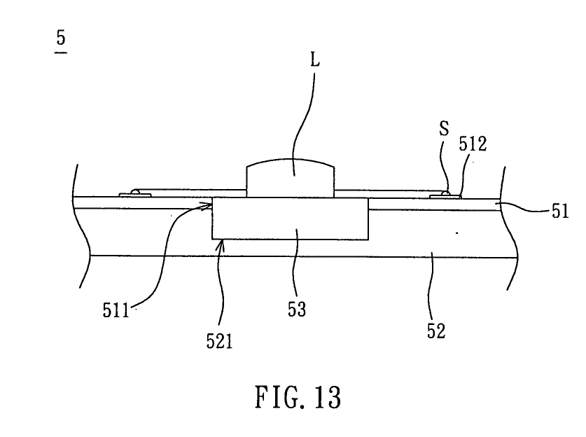

As shown in FIG. 10, the manufacturing method of the light-emitting heat-dissipating device 5 includes steps S11 to S14. As shown in FIGS. 10 and 11, step S11 is performed to provide a supporter 52 having at least one recess 521, wherein the recess 521 is formed on a surface of the supporter 52. Step S12 is performed to dispose at least one thermally conducting element 53 in the recess 521.

As shown in FIG. 12, step S13 is performed to dispose a substrate 51 having at least one slot 511 on the supporter 52. The slot 511 corresponds to the recess 521, and the thermally conducting element 53 is disposed in the slot 511. In practice, the substrate 51 of this embodiment may be the typical printed circuit board or the typical low-temperature co-fired ceramic circuit board, and a circuit layout (not shown) is formed on the surface of the substrate or inside the substrate. The surface of the substrate 51 has a plurality of solder joints 512 connected to the circuit layout. In practice, the thermally conducting element 53 of this embodiment may be higher than, lower than or level with the substrate 51. Herein, the surface of the thermally conducting element 53 is level with the surface of the substrate 51.

As shown in FIG. 13, step S14 is performed to dispose at least one light-emitting package module L on the thermally conducting element 53 and electrically connect the at least one light-emitting package module L with the substrate 51. The connection between the light-emitting package module L and the substrate 51 is not particularly restricted. The connection may be made by way of surface mount technology or object inserting. Herein, the connection with the solder joints 512 is made by way of surface mount technology. The light-emitting package module L is further connected to the solder joints 512 via a conductive object S.

In summary, compared with the prior art, the invention can transfer the heat from the hot junction of the thermally conducting element to the cold junction thereof and then dissipate the heat according to the single orientation of the thermally conducting element. This method can dissipate the heat of the light-emitting package module more effectively and make the light-emitting heat-dissipating device have the uniform temperature distribution so that the luminance and the color of the light-emitting package module achieve the uniform states and the reliability and the heat dissipating efficiency of the light-emitting heat-dissipating device can be enhanced. In addition, when one circuit board is disposed on a supporter, the thickness of the circuit board can be decreased so that the manufacturing cost can be decreased.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting heat-dissipating device, comprising:
at least one light-emitting package module;
a substrate having at least a first recess on a surface; and
at least a thermally conducting element disposed in the first recess, wherein the light-emitting package module is disposed on the thermally conducting element.

2. The light-emitting heat-dissipating device according to claim 1, wherein a top surface of the thermally conducting element is higher, lower than or equal to the surface of the substrate.

3. The light-emitting heat-dissipating device according to claim 1, wherein the thermally conducting element is a heat pipe, a pulsating heat pipe or a loop heat pipe.

4. The light-emitting heat-dissipating device according to claim, 3, wherein a thermal coefficient of the heat pipe is substantially higher than 6000 W/m·K.

5. The light-emitting heat-dissipating device according to claim 1, wherein the thermally conducting element is disposed in the first recess by embedding, adhering or soldering.

6. The light-emitting heat-dissipating device according to claim 1, wherein one end of the thermally conducting element extends out of the substrate and is coupled to a heat dissipation element.

7. The light-emitting heat-dissipating device according to claim 6, wherein the heat dissipation element comprises a heat sink having a plurality of heat-dissipation fins.

8. The light-emitting heat-dissipating device according to claim 7, further comprising a fan disposed on the heat dissipation element to dissipate heat accumulated in the heat dissipation element.

9. The light-emitting heat-dissipating device according to claim 1, wherein the light-emitting package module is a light emitting diode (LED) package module, a light emitting diode array package module, an organic light emitting diode package module or an organic light emitting diode array package module.

10. The light-emitting heat-dissipating device according to claim 1, wherein the substrate is a printed circuit board (PCB) or a low-temperature co-fired ceramic (LTCC) circuit board.

11. The light-emitting heat-dissipating device according to claim 1, wherein the substrate has a circuit layout and a plurality of solder joints formed on the surface of the substrate, the light-emitting package module is connected to the circuit layout of the substrate via the solder joints by surface mount technology (SMT) or object inserting way.

12. The light-emitting heat-dissipating device according to claim 1, further comprising a supporter disposed below the substrate, the supporter having a second recess formed on a surface thereof.

13. The light-emitting heat-dissipating device according to claim 12, wherein the second recess is located corresponding to the first recess, and the thermally conducting element is disposed in the first recess and the second recess.

14. The light-emitting heat-dissipating device according to claim 12, wherein the supporter is made of metal, a thermal-conducting material or a polymer.

15. A method of manufacturing a light-emitting heat-dissipating device, the method comprising the steps of:
providing a substrate having at least a first recess formed on a surface of the substrate;
disposing at least one thermally conducting element in the first recess; and
disposing at least one light-emitting package module on the thermally conducting element.

16. The method according to claim 15, wherein the thermally conducting element is disposed in the first recess by embedding, adhering or soldering.

17. The method according to claim 15, wherein one end of the thermally conducting element extends out of the substrate and is coupled to a heat dissipation element.

18. The method according to claim 17, further comprising a step of providing a fan on the heat dissipation element to dissipate heat accumulated in the heat dissipation element.

19. The method according to claim 15, wherein the substrate has a circuit layout and a plurality of solder joints formed on the surface of the substrate, the light-emitting package module is connected to the circuit layout of the substrate via the solder joints by surface mount technology (SMT) or object inserting method.

20. The method according to claim 15, further comprising providing a supporter disposed below the substrate, the supporter having a second recess formed on a surface thereof, wherein the second recess is located corresponding to the first recess, and the thermally conducting element is disposed in the first recess and the second recess.
